(19) United States
(12) Patent Application Publication
(10) Pub. No.: US 2009/0085107 A1
(43) Pub. Date: Apr. 2, 2009

(54) Trench MOSFET with thick bottom oxide tub

(75) Inventor: Fwu-Iuan Hshieh, Saratoga, CA (US)

Correspondence Address: BO-IN LIN, 13445 MANDOLI DRIVE, LOS ALTOS HILLS, CA, 94022, US

(73) Assignee: Force-MOS Technology Corp.

(21) Appl. No.: 11/904,840

(22) Filed: Sep. 28, 2007

(51) Int. Cl. H01L 29/94; H01L 21/336

(52) U.S. Cl. 257/331; 438/270; 257/E29.345

(57) ABSTRACT

A semiconductor power device includes a plurality of trenched gates. The trenched gates include a thin dielectric layer padded sidewalls of the trenched gate and a tub-shaped thick dielectric layer below a bottom of the trenched gates having a width narrower than the trenched gate. In an exemplary embodiment, the tub-shaped thick dielectric layer below a bottom of the trenched gates further includes a local deposition of silicon oxide (LOCOS) filling in a tub-shaped trench having a narrower width than the trenched gate. In another exemplary embodiment, the tub-shaped thick dielectric layer below a bottom of the trenched gates further comprising a high density plasma (HDP) chemical vapor deposition (CVD) silicon oxide filled in a tub-shaped trench having a narrower width than the trenched gate.

### BACKGROUND OF THE INVENTION

1. Field of the Invention

The invention relates generally to the device configuration and manufacturing methods for fabricating the semiconductor power devices. More particularly, this invention relates to an improved and novel manufacturing process and device configuration for providing the MOSFET device with thick oxide bottom tub for reducing the gate-drain capacitance

2. Description of the Related Art

In order to increase the switching speed of a semiconductor power device, it is desirable to reduce the gate to drain capacitance Crss. A thick oxide formed at the trench bottom of the trench gate is frequently implemented to reduce the gate to drain capacitance. However, a thicker oxide layer formed at the trench bottom may also cause the on-resistance of the semiconductor power device to increase in the meantime thus adversely increasing the power consumptions due to a higher on-resistance.

FIG. 1A shows a standard MOSFET device with a single gate oxide layer. The capacitance Crss is a capacitance between the gate and drain. In order to reduce the capacitance Crss, a thick bottom oxide structure is disclosed in Patents U.S. Pat. Nos. 6,437,386, 6,573,569, and 6,709,930. FIG. 1B shows a LOCOS oxide layer as a thick oxide layer at the trench bottom to reduce the gate-drain capacitance. Furthermore, in U.S. Pat. No. 6,291,298, a deposited oxide layer is formed at the bottom of the trench as shown in FIG. 1C for reduce the gate-to-drain capacitance. However, such thick oxide layer formed near the bottom of the trench also has an undesirable effect of increasing the on-resistance of the MOSFET device.

Therefore, a need still exists in the art of power semiconductor device design and manufacture to provide new manufacturing method and device configuration in forming the semiconductor power devices such that the above discussed problems and limitations can be resolved.

### SUMMARY OF THE PRESENT INVENTION

It is therefore an aspect of the present invention to provide a new and improved semiconductor power device by forming a thick oxide layer at a narrower and deeper trench below the normal trench gate. Such Y-shaped oxide layer structure can significantly reduce the gate-to-drain capacitance without increasing the on-resistance of the MOSFET device. The new and improved device structure and manufacturing method thus provide a solution to overcome the above discussed difficulties and limitations of the MOSFET device.

Another aspect of this invention is to form an improved MOSFET device with thick LOCOS oxide layer at the bottom of a recess trench. The thickness of the LOCOS trench is determined by the depth of the recessed trench filled with the LOCOS oxide. The thickness can be thinner while achieving the same reduction of capacitance because the LOCOS oxide in the recessed trench below the normal trenched gate is two-dimensional LOCOS that wherein the LOCOS oxide layer includes the sidewalls and bottom of the recessed trenches.

Another aspect of this invention is to form an improved MOSFET device with thick HDP CVD oxide layer at the bottom of a recess trench. The thickness of the HDP CVD oxide layer trench is determined by the depth of the recessed trench filled with the HDP CVD oxide. The thickness can be thinner while achieving the same reduction of capacitance because the HDP CVD oxide in the recessed trench below the normal trenched gate is two-dimensional HDP CVD oxide that wherein the HDP CVD oxide layer includes the sidewalls and bottom of the recessed trenches.

Briefly in a preferred embodiment, this invention discloses a semiconductor power device that includes a plurality of trenched gates. The trenched gates include a thin dielectric layer padded sidewalls of the trenched gate and a tub-shaped thick dielectric layer below a bottom of the trenched gates having a width narrower than the trenched gate. In an exemplary embodiment, the tub-shaped thick dielectric layer below a bottom of the trenched gates further comprising a local deposition of silicon oxide (LOCOS) filling in a tub-shaped trench having a narrower width than the trenched gate. In another exemplary embodiment, the tub-shaped thick dielectric layer below a bottom of the trenched gates further comprising a high density plasma (HDP) chemical vapor deposition (CVD) silicon oxide filled in a tub-shaped trench having a narrower width than the trenched gate. In another exemplary embodiment, the semiconductor power device further includes a dopant region surrounding the tub-shaped thick dielectric layer having a higher dopant concentration than an epitaxial layer in a semiconductor substrate for forming and supporting the semiconductor power device therein. In another exemplary embodiment, the semiconductor power device further includes a trenched metal oxide semiconductor field effect transistor (MOSFET) device. In an exemplary embodiment, the semiconductor power device includes an N-channel trenched metal oxide semiconductor field effect transistor (MOSFET) device. And the semiconductor power device further includes a N dopant region surrounding the tub-shaped thick dielectric layer having a higher dopant concentration than an N-type epitaxial layer in a semiconductor substrate for further reduction of on-resistance without degrading breakdown voltage. In an exemplary embodiment, each of the trenched gates have a width of approximately 0.3 um to 1.0 um and the tub-shaped thick oxide layer having a width of approximately 0.2 um to 0.8 um.

Furthermore, this invention discloses a method to form a semiconductor power device. The method of manufacturing a semiconductor power device includes a step of opening plurality of trenches and covering sidewalls and a bottom surface of the trenches with padded layers. The method further includes a step of applying an isotropic etch for vertically etching the trenches into a tub-shaped opening below the bottom surface of the trenches with a width of the tub-shaped opening smaller than a width the trenches covering by the padded layers. In an exemplary embodiment, the process further includes a step of filling the tub-shaped opening below the trenches with a thick dielectric layer. In an exemplary embodiment, the process further includes a step of filling the tub-shaped opening below the trenches with a thick local oxidation of silicon oxide (LOCOS) layer. In an exemplary embodiment, the process further includes a step of filling the tub-shaped opening below the trenches with a thick high-density plasma (HDP) oxide layer.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

FIG. 1A is a cross sectional view of a conventional trenched MOSFET power device with a single oxide layer.

FIGS. 1B and 1C are a cross sectional views of two different conventional trenched MOSFET power device with LOCOS and deposited thick oxide layer at the trench bottom to reduce the gate-to-drain capacitance.

FIGS. 2 and 3 are two alternate embodiments of oxide tub below a normal trenched gate of this invention for reducing the gate-to-drain capacitance without increasing the on-resistance.

FIGS. 4A to 4H are a serial cross sectional views for describing the manufacturing processes to provide a trenched MOSFET device with tub-shaped LOCOS below normal trenched gate.

FIGS. 5A to 5E are a serial cross sectional views for describing the manufacturing processes to provide a trenched MOSFET device with tub-shaped HDP CVD oxide layer below normal trenched gate.

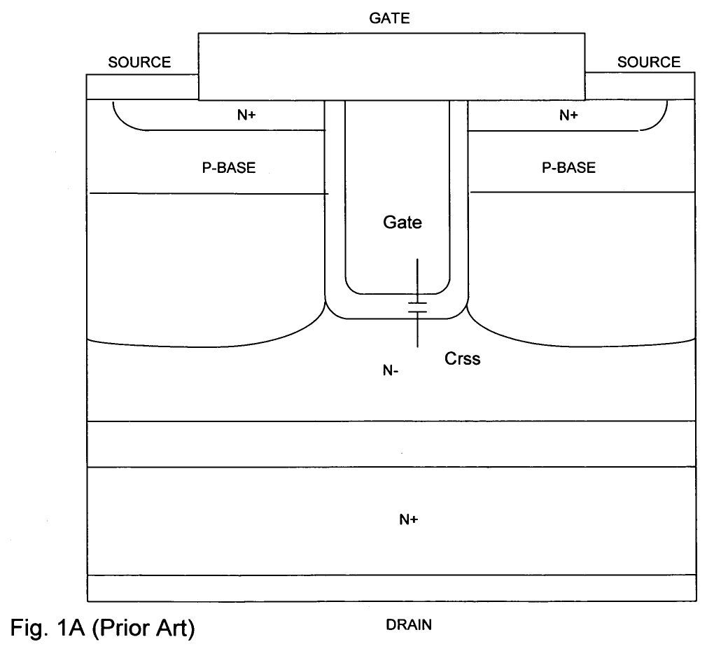

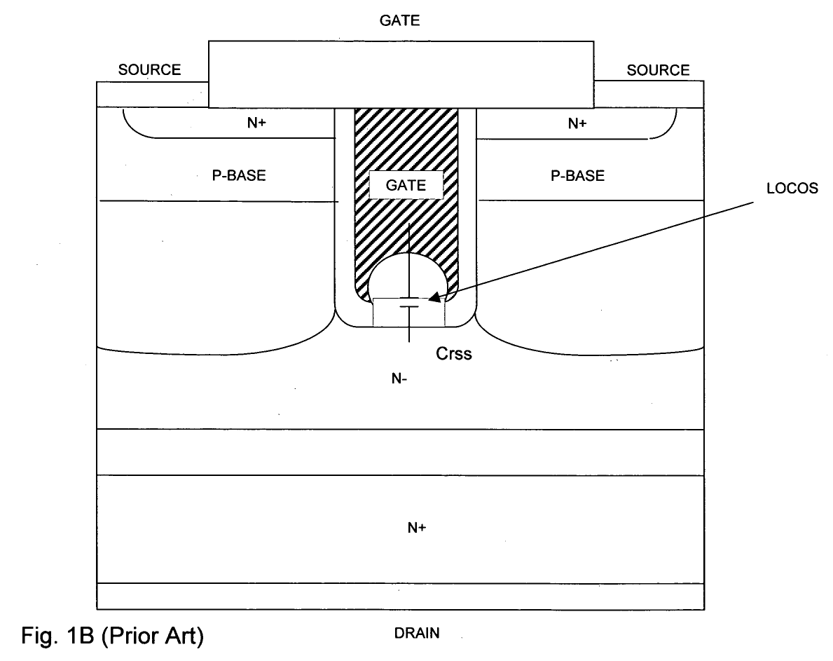

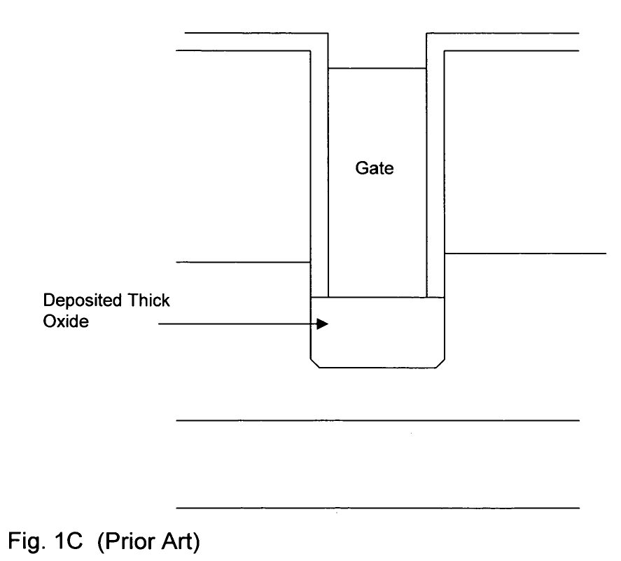

### DETAILED DESCRIPTION OF THE METHOD

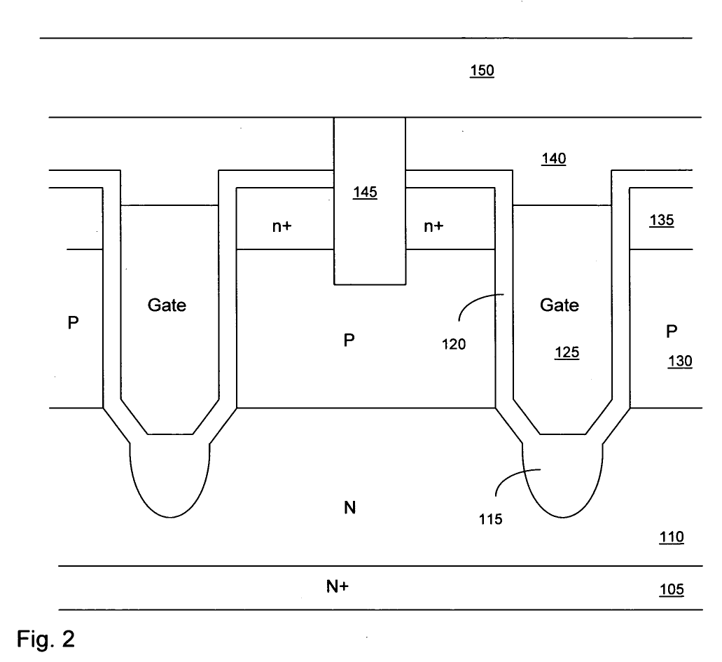

Referring to FIG. 2 for a side cross sectional view of a MOSFET device 100 formed on a N+ substrate 105 supporting an epitaxial layer 110 with trenched polysilicon gates 125. The trenched gates 125 are padded by a gate oxide layer 120 and surrounded by P-body regions 130. The body regions further encompassed source regions 135 formed near the top surface of the epitaxial layer 110 surrounding the trenched gate 125. An oxide insulation layer covering the top surface with contact trenches open through the insulation layer filled with Ti/TiN/W as contact plug inside the contact trenches 145 to contact the source/body regions and the trench contacts to contact the gate (not shown). A top metal layer 150 is formed on top of the trench contacts 145 and patterned into source metal 150 and gate pads (not shown). The MOSFET device has a special oxide layer 115 below the trenched gate 125 formed with a tub shape having a narrow width than the trenched gates 125 thus constituting a Y-shape MOS device, i.e., YMOS power device.

The bottom tub-shaped oxide layer 115 can be a LOCOS oxide layer formed in a recessed trench below the trenched gates 125 as further described below. The LOCOS oxide layer can be formed with less local oxide than the conventional LOCOS oxide layer disclosed in previously patented invention. This is because of the fact that the LOCOS is a two-dimensional LOCOS that includes oxide layer formed on the trench sidewalls as well as the trench bottom. The conventional LOCOS is one-dimensional (1-D) oxidation process because oxide is grown in Y direction, i. e., along the trench bottom direction. In this invention, the LOCOS formed in the recessed trenches, the oxide is grown not only in the Y direction along the trench bottom, the oxide layer is also grown in the X direction along the trench sidewall.

The bottom tub-shaped oxide layer 115 can also be a HDP CVD oxide layer that can be formed with less oxide deposition. A reduced oxide deposition is feasible because the HDP CVD is formed in a recessed trench. The oxide deposition is formed with two-dimensional deposition process and therefore can achieve greater amount of oxide with less deposition compared with conventional oxide deposition processes. Since the oxide tub region has narrower trench width than the top, the oxide tub below the trench bottom as now disclosed requires thinner HDP oxide to refill in the oxide tub region. For example, in a trench that has a trench width of 0.5 um, a requirement of at least 0.25 um HDP Oxide is necessary to refill the trench. This is because each side requires 0.25 um and two sides would require an oxide layer of width of 0.5 um to fill the trench. A narrower tub width below the trench with a trench width of 0.3 um, the width of the HDP oxide layer to fill the oxide tub below the trench bottom would be 0.15 um of HDP oxide and less oxidation is necessary.

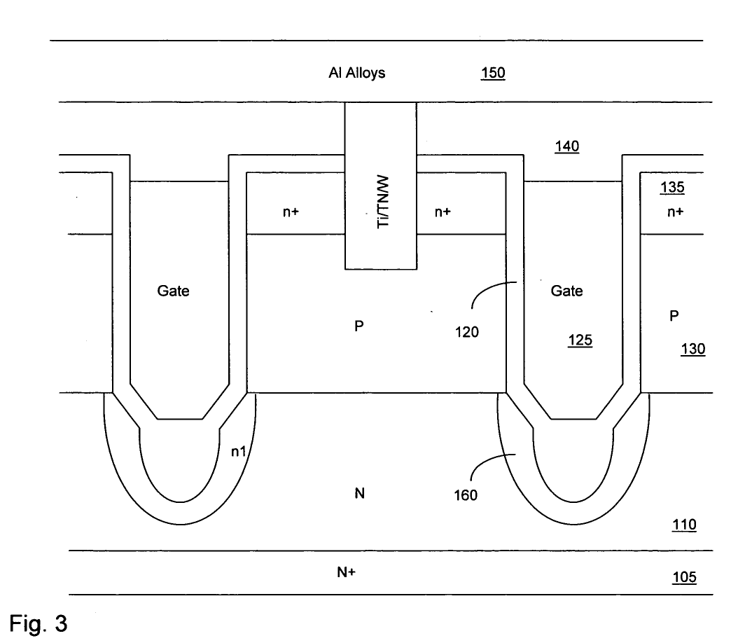

FIG. 3 shows a side cross sectional view of an alternate MOSFET device 100′ with similar device configuration as the MOSFET 100 of FIG. 2. The only difference is that the MOSFET 100′ further includes a heavier N+ doped regions with dopant concentration N1 where N1 is greater than the dopant concentration of N of the epitaxial layer 110. The device has a further advantage of further reduced Rds and lower Qgd because of the higher dopant regions 160 now surrounding the tub-shaped thick oxide layer 115.

Specifically, the MOSFET device 100′ is formed on a N+ substrate 105 supporting an epitaxial layer 110 with trenched polysilicon gates 125. The trenched gates 125 are padded by a gate oxide layer 120 and surrounded by P-body regions 130. The body regions further encompassed source regions 135 formed near the top surface of the epitaxial layer 110 surrounding the trenched gate 125. An oxide insulation layer covering the top surface with contact trenches open through the insulation layer filled with Ti/TiN/W as contact plug inside the contact trenches 145 to contact the source/body regions and the trench contacts to contact the gate (not shown). A top metal layer 150 is formed on top of the trench contacts 145 and patterned into source metal 150 and gate pads (not shown). The MOSFET device has a special oxide layer 115 below the trenched gate 125 formed with a tub shape having a narrow width than the trenched gates 125 thus constituting a Y-shape MOS device, i.e., YMOS power device.

As described above for FIG. 2, the bottom tub-shaped oxide layer 115 can be a LOCOS oxide layer or a HDP CVD oxide layer formed in a recessed trench below the trenched gates 125. The LOCOS oxide or the HDP CVD oxide layer can be formed with less local oxide or oxide deposition than the conventional LOCOS or HDP CVD oxide layer disclosed in previously patented invention. This is because of the fact that the oxide layer is formed in a trench with a two-dimensional process that includes oxide layer formed on the trench sidewalls as well as the trench bottom. The heavier dopant regions 160 provide additional advantages of reducing the on resistance Rds and lower Qgd because the higher dose underneath the oxide tub provides less drift resistance for electron.

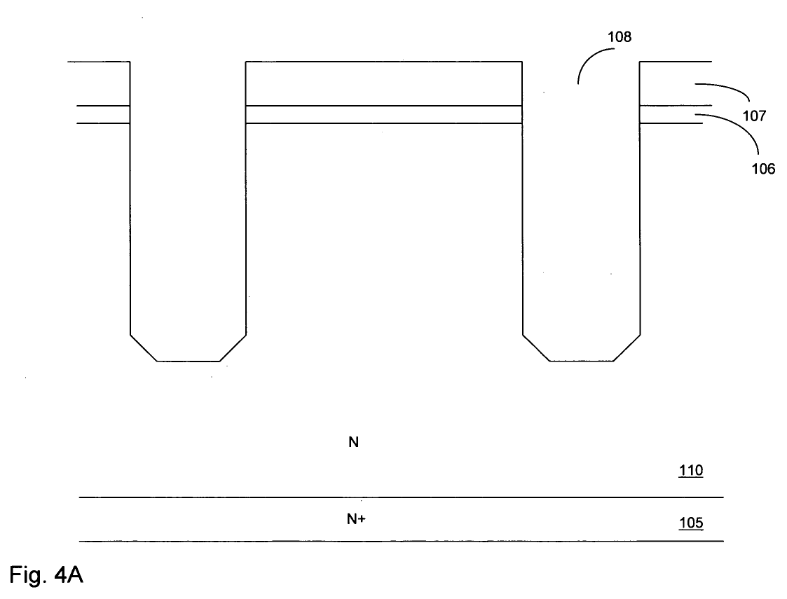

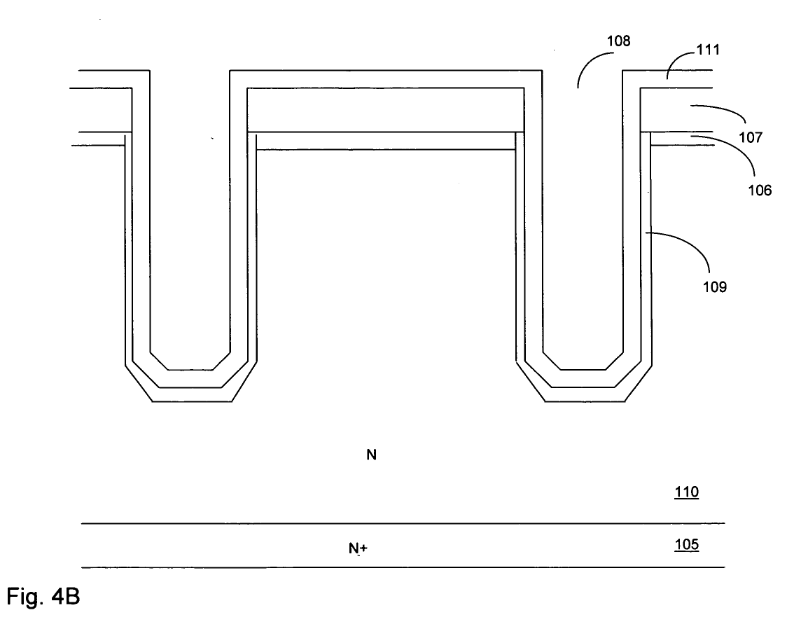

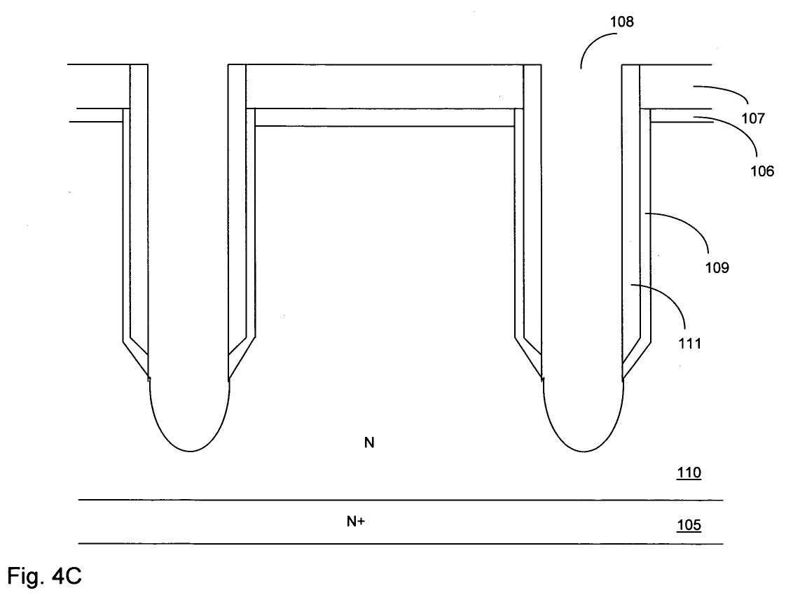

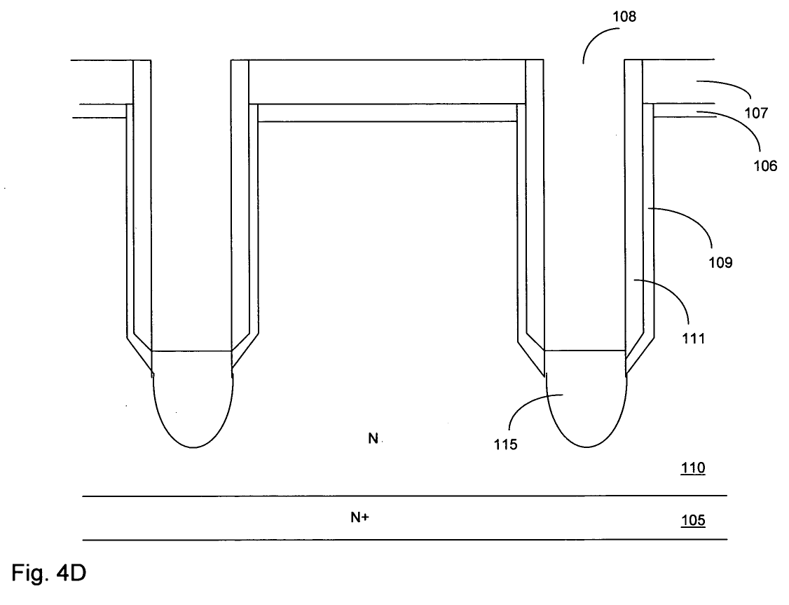

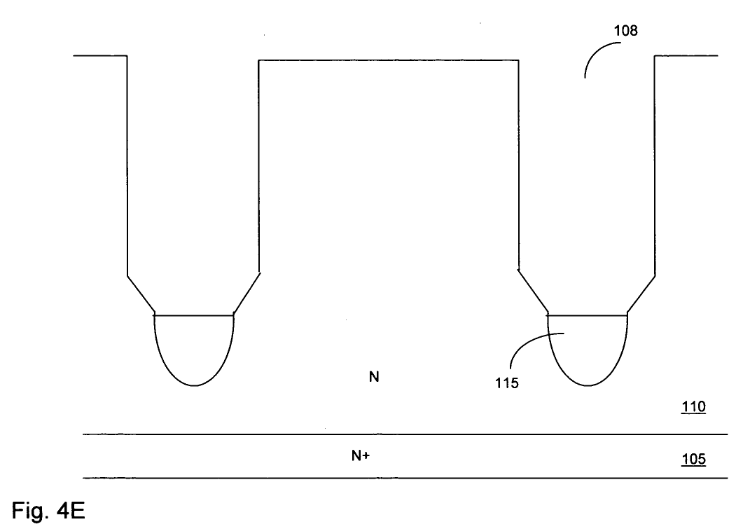

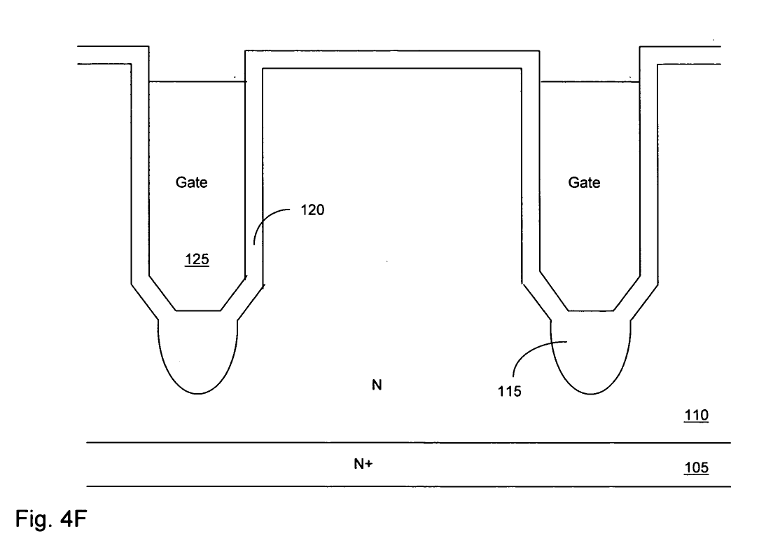

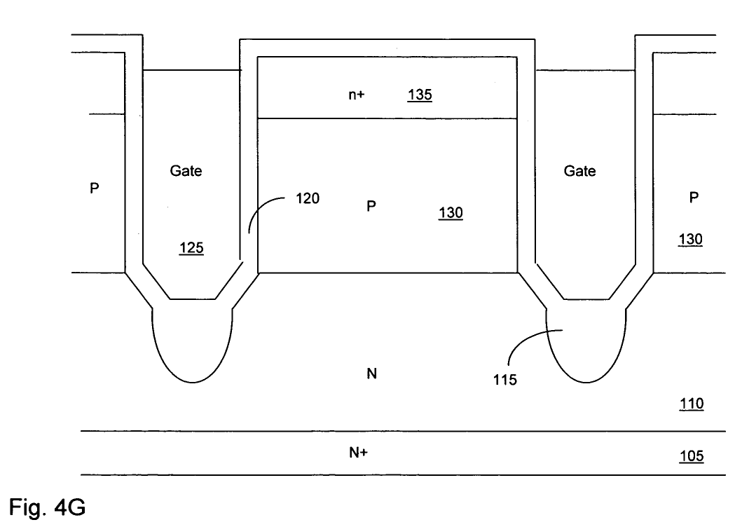

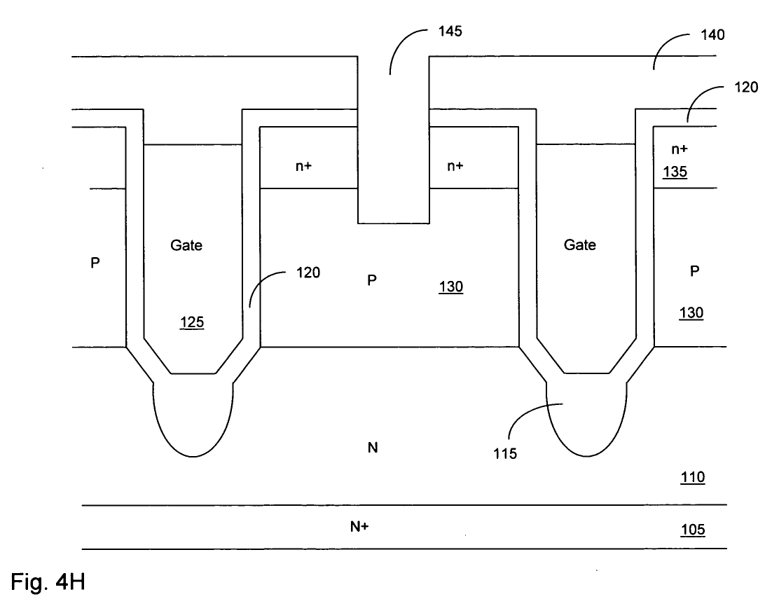

Referring to FIGS. 4A to 4h for a series of cross sectional views to illustrate the processing steps for manufacturing a MOSFET device as shown in FIGS. 2 and 3. In FIG. 4A, a pad oxide layer 106 is grown on top of an epitaxial layer 110 supported on a N+ substrate 105. Then a nitride layer 107 is deposited on top of the oxide pad layer 106. A trench mask (not shown) is applied to open a plurality of trenches 108. In FIG. 4B, a sacrificial oxide layer is grown and then removed followed by growing a gate oxide layer 109 and a nitride deposition for depositing a nitride layer 111. In FIG. 4C, an anisotropic nitride etch is first carried out to remove the nitride layer from the to surface of the substrate and the bottom of the trenches 108 followed by an oxide etch to remove the oxide layer from the trench bottom. Then a trench etch is carried out to etch the trench 108 to remove the bottom portion of the trenches 109 and extend the trenches to a greater depth into the epitaxial layer 110. The nitride layer has much slower rate of oxidation, the nitride layer provides a barrier layer to prohibit oxidation on trench sidewall during LOCOS.

In FIG. 4D, a local oxidation silicon (LOCOS) is carried out to form a LOCOS oxide 115 in the bottom of trenches 109. In FIG. 4E a nitride etch is carried out to remove the nitride layer 107 followed by an oxide etch to remove the pad oxide layer 106. In FIG. 4F, a gate oxide layer 120 is grown followed by the deposition of doped polysilicon layer 125 into the trenches 108. Then a polysilicon etch is performed followed by a chemical-mechanical planarization (CMP) process to remove the polysilicon layer 125 from the top of the trenches. In FIG. 4G, a body mask (not shown) is applied to carrying out a body implant followed by a body diffusion to form the body regions 130. A source mask (not shown) is applied to carry out a source implant followed by a source diffusion to form the source regions 135. An oxide deposition is performed to form an oxide insulation layer 140. A contact mask (not shown) is applied to open contact trenches 145 to contact the source/body regions and the gate (not shown). The manufacturing processes proceed with depositing and patterning of metal layer into source/body contacts and gate pad. Theses standard processes are known and not specifically described.

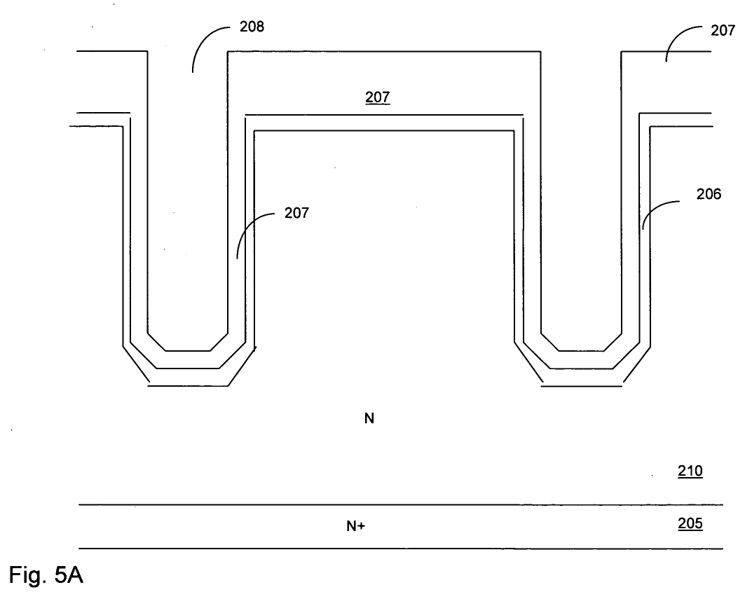

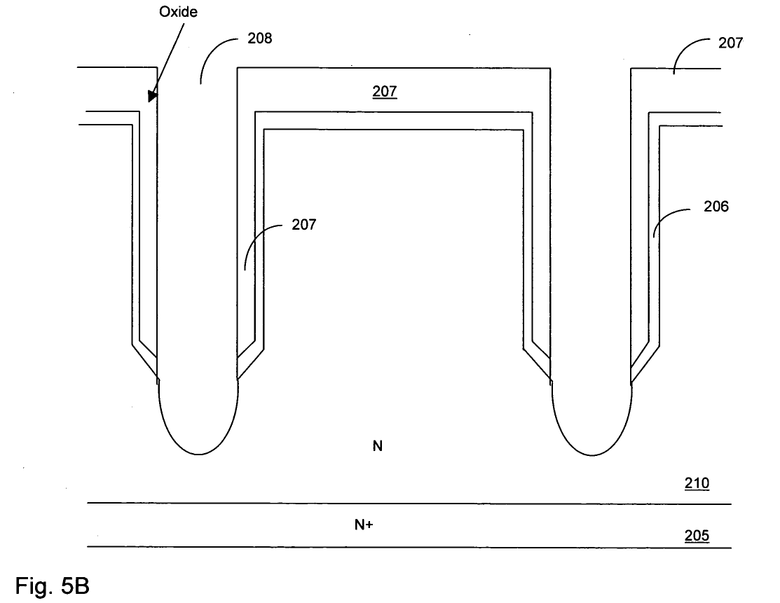

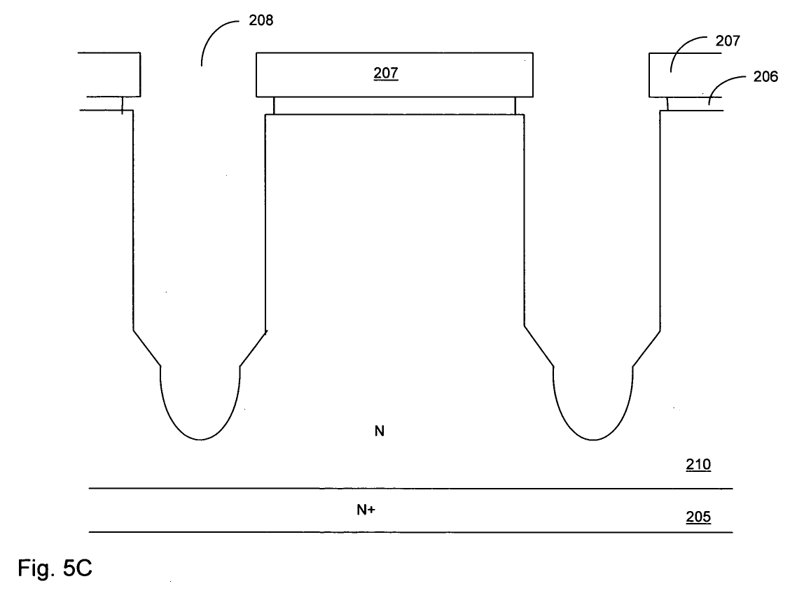

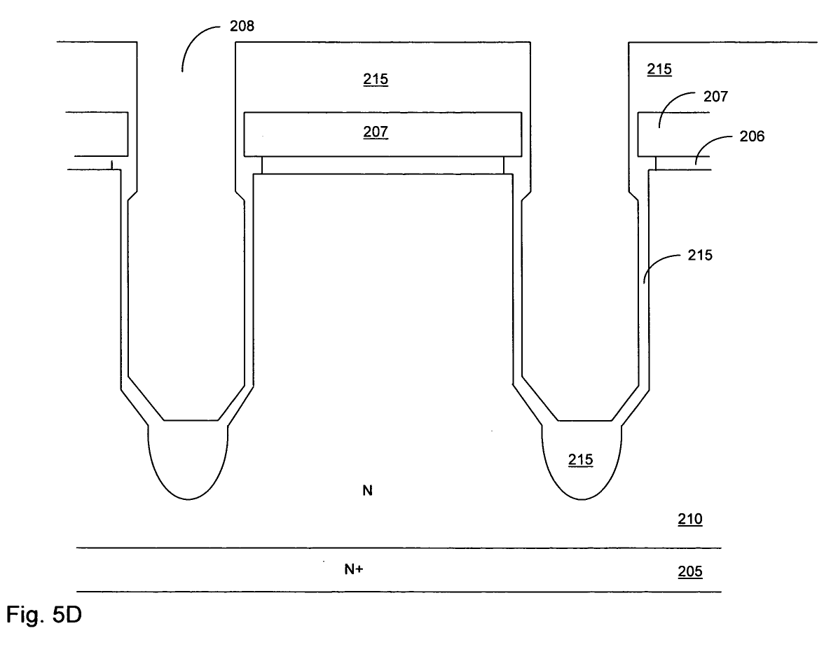

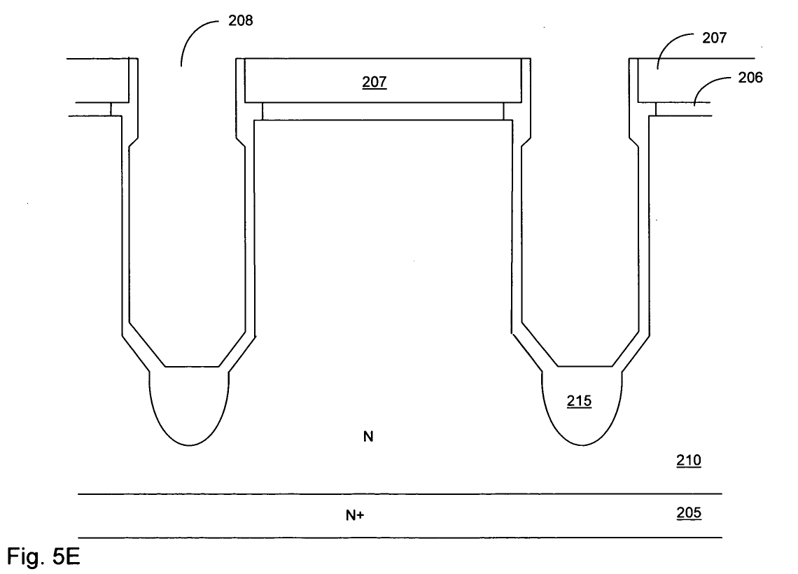

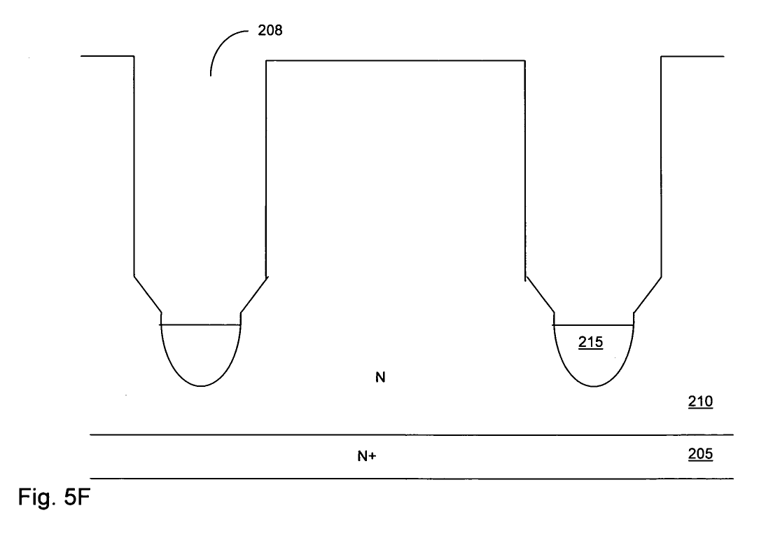

Referring to FIGS. 5A to 5E for a series of cross sectional views to illustrate alternate processing steps for manufacturing a MOSFET device as shown in FIGS. 2 and 3. In FIG. 5A, a trench mask (not shown) is applied to open a plurality of trenches 208 followed by growing and removing a sacrificial oxide layer to repair the trench surface damaged during the trench opening process. A pad oxide layer 206 is grown on top of an epitaxial layer 210 supported on a N+ substrate 205. Then another oxide layer 207 is deposited on top of the oxide pad layer 206. In FIG. 5B, a dry oxide etch is carried out to remove the oxide layers covering the bottom portion of the trenches 208. Then a dry silicon etch is performed to etch the trenches 208 to further extend the trenches 208 with a greater depth into the epitaxial layer 210. The dry etch is an anisotropic etch wherein a process of ion bombardment is first carried out to enhance a vertical etch rate. Therefore, the dry etch remove only the oxide layer from the trench bottom and from the mesa area on top surface surrounding the trenches. The oxide layer on the sidewalls is only slightly etched. In FIG. 5C, a wet oxide etch is carried out to remove the oxide layers from the sidewalls and the bottom of the trenches 208.

In FIG. 5D, a HDP CVD (chemical vapor deposition) oxide layer 215 is deposited. In FIG. 5E, a chemical-mechanical planarization (CMP) process is carried out to remove the HDP layer 215 from the top surface over the oxide layer 207. In FIG. 5F, an oxide removal process is carried out to remove the oxide layers 206 and 207 and the HDP layer 215 form the top and the sidewalls of the trench while leaving the thick HDP layer to fill the bottom tub at the bottom of the trenches 208. The CMP process is different from a wet etch process, which only removes the top oxide but not etch any oxide on trench sidewall and bottom. A LOCOS process is generally preferred since HDP oxide and CMP are more expensive compared to the wet etch process as that performed when a LOCOS oxide layer is formed in filling the oxide tub below the trench bottom according to above descriptions. The processes of manufacturing proceed with the formation of the body and source regions and the source/body and gate metal layer as described above.

Although the present invention has been described in terms of the presently preferred embodiment, it is to be understood that such disclosure is not to be interpreted as limiting. Various alterations and modifications will no doubt become apparent to those skilled in the art after reading the above disclosure. Accordingly, it is intended that the appended claims be interpreted as covering all alterations and modifications as fall within the true spirit and scope of the invention.

I claim:

1. A semiconductor power device comprising:
a plurality of trenched gates comprising a thin dielectric layer padded sidewalls of said trenched gate and a tub-shaped thick dielectric layer below a bottom of said trenched gates having a width narrower than said trenched gate.

2. The semiconductor power device of claim 1 wherein:
said tub-shaped thick dielectric layer below a bottom of said trenched gates further comprising a local oxidation of silicon oxide (LOCOS) filling in a tub-shaped trench having a narrower width than said trenched gate.

3. The semiconductor power device of claim 1 wherein:
said tub-shaped thick dielectric layer below a bottom of said trenched gates further comprising a high density processing (HDP) vapor deposition (CVD) silicon oxide filling in a tub-shaped trench having a narrower width than said trenched gate.

4. The semiconductor power device of claim 1 further comprising:
a dopant region surrounding said tub-shaped thick dielectric layer having a higher dopant concentration than an epitaxial layer in a semiconductor substrate for further reduction of on-resistance.

5. The semiconductor power device of claim 1 further comprising:
a trenched metal oxide semiconductor field effect transistor (MOSFET) device.

6. The semiconductor power device of claim 1 further comprising:
a N-channel trenched metal oxide semiconductor field effect transistor (MOSFET) device.

7. The semiconductor power device of claim 1 further comprising:
a N-channel trenched metal oxide semiconductor field effect transistor (MOSFET) device; and
a N dopant region surrounding said tub-shaped thick dielectric layer having a higher dopant concentration than an N-type epitaxial layer in a semiconductor substrate for further reducing an on-resistance.

8. The semiconductor power device of claim 1 further comprising:
a P-channel trenched metal oxide semiconductor field effect transistor (MOSFET) device.

9. The semiconductor power device of claim 1 further comprising:
a P-channel trenched metal oxide semiconductor field effect transistor (MOSFET) device; and
a P-dopant region surrounding said tub-shaped thick dielectric layer having a higher dopant concentration than an P-type epitaxial layer in a semiconductor substrate for forming and supporting said semiconductor power device therein.

10. The semiconductor power device wherein:
said plurality of trenched gates having a width of approximately 0.3 um to 1.0 um and said tub shaped thick oxide layer having a width of approximately 0.2 um to 0.8 um

11. A method of manufacturing a semiconductor power device comprising:
opening plurality of trenches and covering sidewalls and a bottom surface of said trenches with padded layers; and
applying an isotropic etch for vertically etching said trenches into a tub-shaped opening below said bottom surface of said trenches with a width of said tub-shaped opening smaller than a width said trenches covering by said padded layers.

12. The method of claim 11 further comprising:
filling said tub-shaped opening below said trenches with a thick dielectric layer.

13. The method of claim 11 further comprising:
filling said tub-shaped opening below said trenches with a thick local oxidation of silicon oxide (LOCOS) layer.

14. The method of claim 11 further comprising:
filling said tub-shaped opening below said trenches with a thick high density plasma (HDP) oxide layer.

15. The method of claim 11 wherein:
said step of covering said sidewalls of said trenches with padded layers further comprising covering sidewalls of said trenches with a nitride layer having a lower rate of oxidation while a thick oxide layer is formed in said tub-shaped opening below said trenches with a higher oxidation rate.

16. The method of claim 11 further comprising:
filling said tub-shaped opening below said trenches with a thick local oxidation of silicon oxide (LOCOS) layer with a two-dimensional oxidation in two directions (2D) along a bottom surface and sidewalls of said tub-shaped opening below said trenches.

17. The method of claim 11 further comprising:
filling said tub-shaped opening below said trenches with a thick high density plasma (HDP) oxide layer.

18. The method of claim 11 further comprising:
implanting a dopant region surrounding said tub-shaped opening below said trenches for further reducing an on resistance of said semiconductor power device.
